(19) United States
(12) Patent Application Publication
(10) Pub. No.: US 2010/0131808 A1
(43) Pub. Date: May 27, 2010

(54) Method For Testing Memory

(76) Inventors: Bei-Chuan Chen, Hsinchu (TW); Li-Hsiang Chan, Hsinchu (TW); Shih-Kai Huang, Hsinchu (TW)

Correspondence Address: LIN & ASSOCIATES INTELLECTUAL PROPERTY, INC., P.O. BOX 2339, SARATOGA, CA, 95070-0339, US

(21) Appl. No.: 12/277,463

(22) Filed: Nov. 25, 2008

(51) Int. Cl. G11C 29/04; G06F 11/22

(52) U.S. Cl. 714/719; 714/E11.145

(57) ABSTRACT

A memory testing method is provided, by using the computation capability of a controller to receive the testing command the program code of a testing PC to generate random data or use an algorithm to generate testing data of specific format. Then, the method writes the data directly to the flash memory and read the data from the memory again to compare with the original data. The comparison result is transmitted back to the testing PC. The method greatly reduces the memory access frequency and I/O load of the testing PC so as to improve the testing efficiency.

### FIELD OF THE INVENTION

The present invention generally relates to a method for testing memory, and more specifically to a method using built-in controller with testing capability for testing memory.

### BACKGROUND OF THE INVENTION

Flash memory is the most popular storage media in the market, and is widely applied to embedded systems. Flash memory is a solid state, no volatile, rewritable memory, with the operation similar to a hybrid of RAM and harddisk. Like DRAM, flash memory stores the data bits in the memory units. However, the data remains in the memory even when the power is off. With the advantages of high speed, durability, and low voltage requirements, flash memory is suitable for a wide range of devices, such as digital camera, cell phone, printer, palm PC, pager and audio recorder.

FIG. 1 shows a schematic view of c conventional memory testing system. As shown in FIG. 1, memory testing system 1 includes a testing PC 10 and a sorting board 20, where testing PC 10 is connected to sorting board 20 through a transmission interface, such as USB interface. Sorting board 20 includes a controller 30 and a memory 40. Controller 30 is usually a control chip or a control module with a control chip. Testing PC 10 issues test commands and test data, received by controller 30 and written to memory 40, or controller 30 reads from memory 40 and sends back to testing PC 10. Then, testing PC performs data comparison to confirm whether the memory is normal. The testing result is recorded, including the damaged block addresses and the total number of damaged blocks.

FIG. 2 shows a flowchart of a conventional memory testing technology. As shown in FIG. 2, memory testing starts with step S10, and proceeds to step S12. Step S12 is for testing PC to issue test commands and enters step S14. Step S14 is for testing PC to generate test data and transmit to controller, and enters step S16. Step S16 is for controller to write the test data into memory, and enters step S18. Step S18 is for testing PC to issue read command, and enters step S20. Step S20 is for controller to read the data stored in memory and transmit the data to testing PC, and enters step S22. Step S22 is for testing PC to compare the test data and the received stored data, and enters step S24. Step S24 is for testing PC to record the testing result, and enters step S26. In step S26, if all the memory tests are done, enters step S30 and terminate the process; otherwise, return to step S14.

The aforementioned test operation is the low level comparison in the taxonomy based on the test data, and relies heavily on the scanning testing program of the testing PC and the efficiency of the testing PC. This is because the testing PC will perform a large amount of computation when testing data, including generating testing data, reading and writing data and data comparison of reading. Therefore, finding a balance between the correctness of testing and the scanning efficiency is an important issue.

However, the disadvantage of using low-level comparison approach for memory scanning testing is that the CPU of the testing PC usually stays in the state of high load and frequent memory access.

Another testing method is high level comparison. Testing PC uses controller to write the testing file into the memory, and reads the stored file from the memory for comparison against the testing file. This method follows the system logic to test the memory access through specific files. By writing a large amount of file data in batches to the memory and then read for comparison, the high level method can test whether the memory is normal. Compared with the low level comparison method, the high level approach greatly reduces the access frequency.

However, while the high level comparison method relies entirely on the testing PC and is suitable for developing efficient testing programs, the high level approach cannot achieve the accuracy of the memory block state as the low level approach.

As the memory chip size decreases rapidly in recent years, the circuit is more complicated and requires operating at high frequency. The stability of the memory dice is a challenge to the semiconductor industry. If the memory characteristics are not known in advance, the quality of the memory dice may be challenged. It becomes an important issue to test the memory in a cost-effective and accurate manner. This is especially important as the complexity, capability and density of flash memory are increasing and the testing uncertainty may also increase as a result. With the manufacturing technology emphasizes on miniaturization, different parts of the same chip may exhibit different electrical characteristics. If the same testing process is applied, the yield ratio may also reduce.

Therefore, it is imperative to devise a memory testing method to meet the demands of fast, accurate and cost-effective testing.

### SUMMARY OF THE INVENTION

The primary object of the present invention is to provide a memory testing method, by using an automated comparison testing process. The testing process uses the computation of the controller to generate random data or data of specific format after receiving test command of the testing PC, performs writing, reading and comparison directly to the memory, such as flash memory, and returns the testing result to the testing PC so as to reduce the I/O load to the memory by testing PC and accelerate the memory testing.

Another object of the present invention is to provide a memory testing method, where testing PC is only responsible for sending proprietary command and partial compiled data with low level comparison capability to the controller and then activate the testing process. The controller automatically erases all the memory blocks, and writes to all the pages of each block with data generated by an algorithm of the controller. When reading and comparing the data from the pages of each block, the controller uses an algorithm to compare the read data and the original data to determine whether the memory blocks are normal. Therefore, the major testing is performed by the controller so as to reduce the data load of the transmission interface and the computation load of testing PC to improve the testing efficiency.

It is worth noting that in the low level comparison process, an algorithm is used to generate different data for different memory addresses for writing, read and comparison. The present invention does not use fixed data for flash memory testing; instead, the present invention uses the comparison provided by the testing PC. Compared with the conventional testing mode, the present invention provides both the accuracy of the low level comparison and the efficiency of high level comparison. The advantage of the present invention is to accomplish the complicated scanning testing with minimum load of CPU, minimum data transmission and shorter testing time.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a conventional memory testing system;

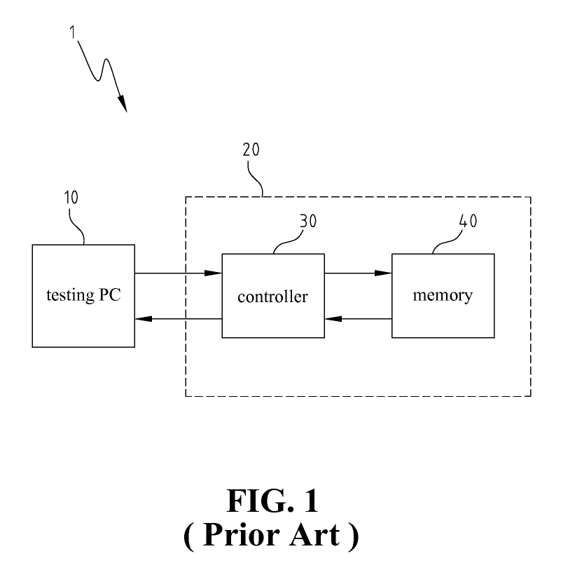

FIG. 2 shows a flowchart of a conventional memory testing method;

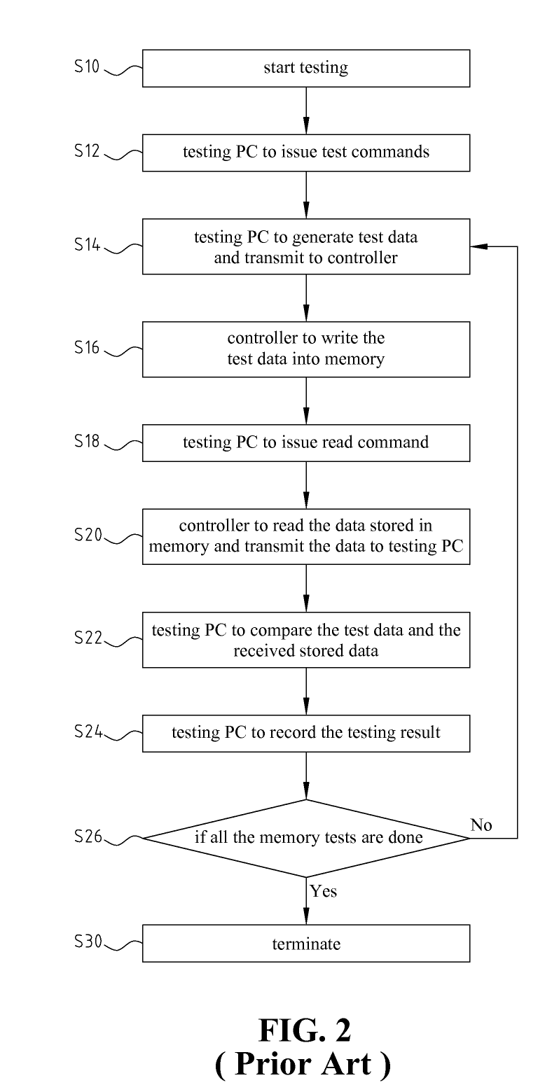

FIG. 3 shows a schematic view of a memory testing system of the present invention; and

FIG. 4 shows a flowchart of a memory testing method of the present invention.

### DETAILED DESCRIPTION OF THE PREFERRED EMBODIMENTS

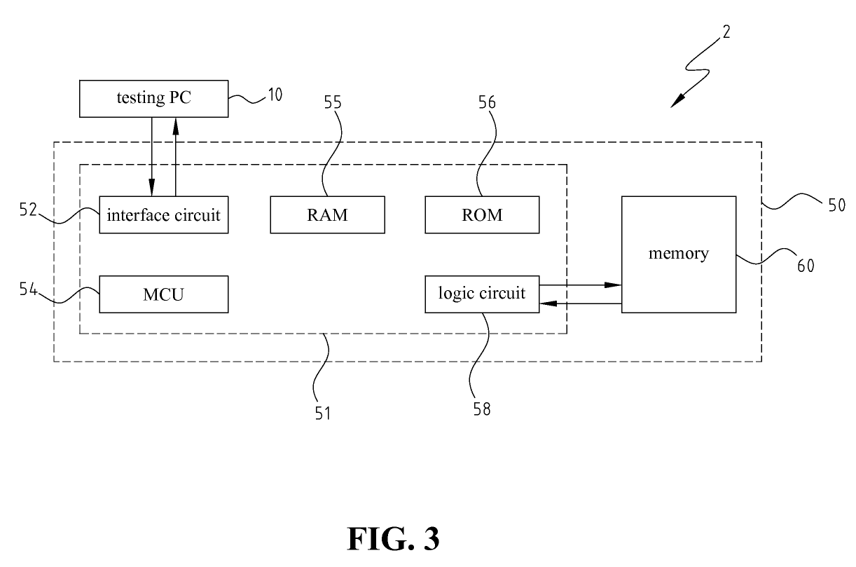

FIG. 3 shows a schematic view of the memory testing system of the present invention. As shown in FIG. 3, memory testing system 2 includes a testing PC 10 and a testing board 50, where testing board 50 further includes a controller 51 and a memory 60 to be tested. Controller 51 includes an interface circuit 52, an MCU 54, a RAM 55, a ROM 56 and a logic circuit 58. Interface circuit 52 is for receiving data from testing PC 10 or transmitting data to testing data 10. MCU 54 controls the entire process of controller 51. RAM 55 provides storage for data access. Logic circuit 58 is for processing accesses to memory 60. ROM 56 is for storing the program code compiled by testing PC 10, including algorithm for generating test data, data comparison processing and recording test result.

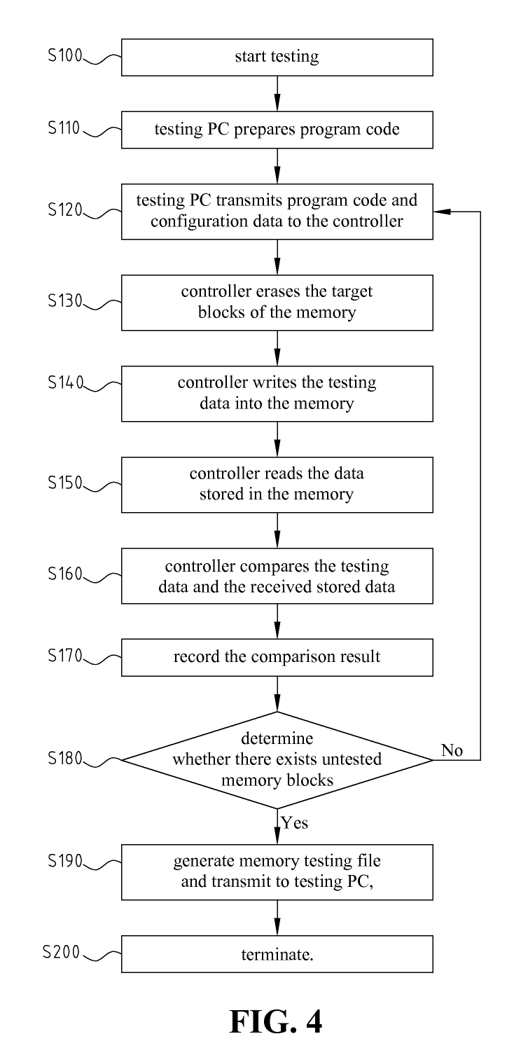

FIG. 4 shows a flowchart of a memory testing method of the present invention. As shown in FIG. 4, the memory testing process of the present invention starts with step S100 and proceeds to step S110. In step S110, testing PC prepares program code and the process enters step S120. In step 120, testing PC transmits program code and configuration data to the controller and the process enters step S130. In step 130, the controller erases the target blocks of the memory and the process enters step S140. In step S140, the controller writes the testing data into the memory and the process enters step S150. In step S150, the controller reads the data stored in the memory and the process enters step S160. In step S160, the controller compares the testing data and the received stored data and the process enters step S170. In step S170, the comparison result is recorded and the process enters step S180. Step S180 is to determine whether there exists untested memory blocks; if so, the process returns to step S130; otherwise, the process enters step S190. Step S190 is to generate memory testing file and transmit to testing PC, and then the process enters step S200 to terminate.

The program code of step S110 may include the algorithm for generating testing data, such as the testing data of low level comparison, and the program code can also provide the low level comparison operation so as to accurately determine whether individual blocks are normal. Because the operation is executed by the logic circuit of the controller, the load on the testing PC is greatly reduced and the overall test efficiency is improved.

The program code of step S110 may further include the algorithm for generating the testing files for high level comparison, for writing to memory in batches to reduce the memory access frequency.

The memory testing files of step S190 includes marking the normal blocks when the comparison result is correct, and marking the damaged blocks when the comparison result is incorrect for generating the testing tables marking normal and damaged blocks.

In summary, the method of the present invention can greatly reduce the memory access and the load of the testing PC to improve the testing efficiency.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A memory testing method, for testing data writing and reading functions of a memory, said method comprising the following steps of:
step A: a testing PC preparing a program code and a configuration data, said program code comprising an algorithm for generating a testing data, an operation for data comparison, and an operation for recording testing result, and entering step B;
step B: said testing PC transmitting said program code to a controller, said controller comprising an interface circuit, a microprocessor unit(MCU), a RAM, a ROM and a logic circuit, where said interface circuit for receiving said program code and said configuration data and transmitting to said ROM, said logic circuit for processing data access to said memory, entering step C;
step C: said logic circuit of said controller erasing a target block of said memory, entering step D;
step D: aid logic circuit of said controller writing said testing data to said target block of said memory, entering step E;
step E: aid logic circuit of said controller reading a stored data from said target block of said memory, entering step F;
step F: aid logic circuit of said controller comparing said testing data and said read stored data, entering step G;
step G: said controller recording a comparison result, entering step H;
step H: if existing untested memory blocks in said memory, returning to step C; otherwise, entering step I;
step I: generating a memory testing file and transmitting to said testing PC, entering step J;
step J: terminating.

2. The memory testing method as claimed in claim 1, wherein said MCU captures said program code in said ROM for controlling said logic circuit to execute said algorithm for generating said testing data, performing said data access operation to said memory, performing said data comparison operation and recording said testing result.

3. The memory testing method as claimed in claim 1, wherein said comparison result of said step G is to mark said target block as a normal block when comparison of said testing data and said stored data is correct, and mark said target block as damaged block when comparison of said testing data and said stored data is incorrect.

4. The memory testing method as claimed in claim 1, wherein said RAM provides a temporary storage for data to said controller.

5. The memory testing method as claimed in claim 1, wherein said memory testing file of said step I comprises said comparison result of said step G.

6. The memory testing method as claimed in claim 1, wherein said interface circuit comprises a USB interface circuit.

7. The memory testing method as claimed in claim 1, wherein said memory comprises a flash memory.
